(19) United States
(12) Patent Application Publication
(10) Pub. No.: US 2025/0180655 A1
(43) Pub. Date: Jun. 5, 2025

(54) STORAGE BATTERY MANAGEMENT DEVICE AND METHOD FOR MANAGING STORAGE BATTERY

(71) Applicant: MUSASHI SEIMITSU INDUSTRY CO., LTD., TOYOHASHI-SHI, AICHI (JP)

(72) Inventor: Kenji HAMADA, TOYOHASHI-SHI, AICHI (JP)

(21) Appl. No.: 18/689,122

(22) PCT Filed: Sep. 28, 2021
(86) PCT No.: PCT/JP2021/035619

§ 371 Date: Feb. 7, 2025

(51) Int. Cl. G01R 31/374; G01R 31/367; G01R 31/3828; G01R 31/3842; H01M 10/48

(52) U.S. Cl. CPC G01R 31/374; G01R 31/367; G01R 31/3828; G01R 31/3842; H01M 10/486

(57) ABSTRACT

A storage battery management device manages a storage battery having SOC-OCV characteristics including a first region in which an OCV change rate is a predetermined value or less and a second region in which the OCV change rate exceeds the predetermined value. The device includes a coulomb counting processing unit that calculates capacity of the storage battery an SOC estimation unit that estimates the SOC of the storage battery, an OCV acquisition unit that acquires the OCV of the storage battery, and a correction unit that corrects the FCC of the storage battery used in the SOC estimation unit based on the correction SOC when a correction condition is satisfied that includes as a necessary condition that the correction SOC is within the second region.

### TECHNICAL FIELD

The technology disclosed herein relates to a storage battery management device and a method for managing a storage battery.

### BACKGROUND ART

The OCV (open circuit voltage) method is known as a method for estimating the SOC (state of charge or charge rate) of storage batteries (see, e.g., Patent Literature 1). The OCV method acquires the OCV of a storage battery to estimate the SOC based on the correspondence between the acquired OCV and the SOC-OCV (open circuit voltage) characteristic curve of the storage battery. In the OCV method, the period for estimating the SOC can be limited to the period when the OCV of the storage battery is available, and the SOC of the storage battery may not be estimated accurately for storage batteries with SOC-OCV characteristics that include a region where the absolute value of a change amount of the OCV relative to the change amount of the SOC is relatively small (e.g., plateau region).

The current integration method is another well-known method for estimating the SOC of storage batteries. In the current integration method, the change amount of the capacity of the storage battery from the initial state is calculated by integrating the measurement results of the current flowing through the storage battery, and the SOC is estimated based on the initial capacity, the calculated capacity change, and the FCC (full charge capacity). Unlike the OCV, the current integration method can estimate the SOC without being affected by the limitation of the period during which the OCV is available or by the plateau region; however, the SOC may not be accurately estimated due to measurement errors in the current measurement unit that measures the current flowing through the storage battery. With regard to this, a method that combines the current integration method and the OCV method is known (see, e.g., Patent Literature 2). This method resets the initial capacity to the SOC estimated by the OCV method at each point in time when the OCV can be measured, thereby eliminating the integration error caused by the measurement error of the current measurement unit.

### CITATION LIST

### Patent Literature

Patent Literature 1: JP 2021-081244 A
Patent Literature 2: JP 2020-060581 A

### SUMMARY OF INVENTION

### Technical Problem

In the current integration method, the factors that affect the accuracy of SOC estimation may include not only measurement errors in the current measurement unit but also errors between the assumed state and the actual state of the storage battery (hereinafter referred to as “storage battery state error”). Factors that may cause the storage battery state error include individual differences in the battery at the time of shipment and aging. For example, if the storage battery state error is relatively large, the FCC used in the current integration method may also contain a significant error, which may affect the accuracy of the SOC estimation more significantly than the measurement error of the current measurement unit. Not only in the current integration method but also in the methods mentioned above that use both the current integration method and the OCV method, as long as the FCC with low accuracy is used, the SOC estimated by the current integration method will continuously contain errors caused by the storage battery state error in addition to measurement errors in the current measurement unit. As a result, the SOC cannot be accurately estimated by the current integration method.

Disclosed herein is technology that can solve the problems mentioned above.

### Solution to Problem

The technology disclosed herein can be implemented in the following aspects.
(1) A storage battery management device disclosed herein is a device for managing a storage battery having SOC-OCV characteristics including a first region in which an OCV change rate, which is the absolute value of a change amount of the OCV relative to the change amount of the SOC, is a predetermined value or less, and a second region in which the OCV change rate exceeds the predetermined value, comprising: a current measurement unit that measures the current flowing through the storage battery; a coulomb counting processing unit that calculates the capacity of the storage battery by integrating the current measured by the current measurement unit; an SOC estimation unit that estimates the SOC of the storage battery based on a reference time SOC (an SOC at a reference time), the change amount of the capacity of the storage battery from the reference time calculated by the coulomb counting processing unit, and the FCC of the storage battery; an OCV acquisition unit that acquires the OCV of the storage battery; and a correction unit that corrects the FCC of the storage battery used in the SOC estimation unit based on the correction SOC when a correction condition is satisfied that includes as a necessary condition that the correction SOC, which is the SOC corresponding to the OCV of the storage battery acquired by the OCV acquisition unit, is within the second region.

In this storage battery management device, the SOC of the storage battery is estimated based on the reference time SOC, the change amount of the capacity of the storage battery based on the integration of the current flowing through the storage battery, and the FCC of the storage battery (hereinafter referred to as “SOC estimation based on the current integration method”). The FCC used in this SOC estimation based on the current integration method is corrected based on the correction SOC. The correction SOC is the SOC corresponding to the OCV of the storage battery acquired by the OCV acquisition unit and is the SOC that is within the second region (the region where the OCV change rate, which is the absolute value of the OCV change amount relative to the SOC change amount, exceeds a predetermined value). When the SOC is within the second region, the accuracy of acquiring the SOC corresponding to the OCV is higher than when the SOC is within the first region (the region where the above OCV change rate is below the predetermined value). The correction SOC acquired with this relatively high accuracy reflects the actual state of the storage battery (such as individual differences and aging of the storage batteries) more accurately than the SOC estimated based on the current integration method by virtue of the fact that there is no integration error. Therefore, this correction SOC can be used to accurately correct the FCC used for the SOC estimation based on the current integration method. As a result, this storage battery management device can correct the FCC and perform the SOC estimation based on the current integration method accurately.
(2) In the above storage battery management device, the correction unit may be configured to correct the FCC of the storage battery used in the SOC estimation unit according to the difference between the reference time SOC and the correction SOC and the change amount of the capacity of the storage battery from the reference time. According to this storage battery management device, since the FCC is corrected based on the difference between the reference time SOC and the correction SOC, which is correlated with the actual state change of the storage battery, the SOC estimation based on the current integration method can be performed more accurately.
(3) The above storage battery management device may be configured to further include a temporary correction unit that temporarily corrects the FCC of the storage battery based on a temporary correction SOC, which is a SOC on the estimated SOC side in the first region where the correction SOC is located when the correction SOC is in the first region, and the estimated SOC estimated by the SOC estimation unit is outside the first region where the correction SOC is located. According to this storage battery management device, even when the correction SOC is not within the second region, the temporary correction enables accurate SOC estimation based on the current integration method.
(4) The above storage battery management device may be configured to further include a history unit that records a history of the correction of the FCC of the storage battery in the correction unit each time the correction conditions are satisfied, wherein the correction condition may further include as a necessary condition that an average value of the FCC correction amount for the most recent predetermined number of times (two or more times) recorded in the history unit is a threshold value or more. This storage battery management device can suppress a decrease in the accuracy of the FCC correction due to noise or measurement errors in the current measurement unit, for example.
(5) The above storage battery management device may be configured to further include a temporary correction unit that temporarily corrects the reference time SOC based on a temporary correction SOC, which is the SOC on the estimated SOC side in the first region where the correction SOC is located when the correction SOC is in the first region, and the estimated SOC estimated by the SOC estimation unit is outside the first region where the correction SOC is located, wherein the correction condition may further include as a necessary condition that the temporary correction is not performed for a period corresponding to the predetermined number of times. This storage battery management device can suppress errors caused, e.g., by the execution of temporary correction from adversely affecting the judgment of whether or not the FCC correction is necessary.
(6) In the above storage battery management device, the SOC-OCV characteristics of the storage battery may be configured to include a plurality of the second regions, and the correction condition may further include as a necessary condition that the reference time SOC is within a second region different from the correction SOC. This storage battery management device can reduce the burden of performing the FCC correction that would otherwise be performed even when, e.g., the reference time SOC and the correction SOC are within the same second region, and the amount of charge transfer in the storage battery is extremely small and does not require FCC correction,
(7) In the above storage battery management device, the correction condition may be configured to further include as a necessary condition that the difference between the reference time SOC and the correction SOC is a lower limit or more. This storage battery management device can reduce the burden of performing the FCC correction that would otherwise be performed even when, e.g., the difference between the reference time SOC and the correction SOC (the amount of charge transfer in the storage battery) is extremely small, and FCC correction is not required.
(8) The above storage battery management device may be configured to further include a temperature measuring unit that measures the temperature of the storage battery, and the correction condition may further include as a necessary condition that the temperature measured by the temperature measuring unit is within a predetermined temperature range. This storage battery management device can suppress a decrease in FCC correction accuracy due to the storage battery temperature being outside the predetermined temperature range.
(9) The above storage battery management device may be configured to further include an SOC update unit that updates the reference time SOC to the correction SOC when the correction condition is satisfied. This storage battery management device can suppress a decrease in the estimation accuracy of the SOC of the storage battery due to an integration error of the current caused by the current measurement unit, for example.
(10) A method disclosed herein is a method for managing a storage battery having SOC-OCV characteristics including a first region in which an OCV change rate, which is the absolute value of a change amount of the OCV relative to the change amount of the SOC, is a predetermined value or less, and a second region in which the OCV change rate exceeds the predetermined value, including: a step of measuring a current flowing through the storage battery; a step of calculating the capacity of the storage battery by integrating the measured current; a step of estimating the SOC of the storage battery based on the reference time SOC, the calculated change amount of the capacity of the storage battery from the reference time, and the FCC of the storage battery; a step of acquiring the OCV of the storage battery; and a step of correcting the FCC of the storage battery used in the process of estimating the SOC of the storage battery based on the correction SOC when a correction condition is satisfied that includes as a necessary condition that the correction SOC, which is the SOC corresponding to the acquired OCV of the storage battery, is within the second region. This method for managing a storage battery corrects the FCC, thereby performing the SOC estimation based on the current integration method accurately.

The technology disclosed herein can be implemented in various aspects, such as a storage battery management device, a battery device equipped with a storage battery management device and a storage battery, a method of managing those devices, a computer program that implements those methods, and a non-temporary recording medium that records that computer program, among others.

### BRIEF DESCRIPTION OF DRAWINGS

FIG. 1 is an explanatory view schematically illustrating a configuration of a battery device 100 in an embodiment.

FIG. 2 is an explanatory view schematically illustrating SOC-OCV characteristics of a storage battery 12.

FIG. 3 is an explanatory view illustrating an example of an SOC-OCV table T1.

FIG. 4 is an explanatory view illustrating an example of region classification-OCV table T2.

FIG. 5 is a flowchart showing an OCV acquisition process.

FIG. 6 is a flowchart showing a correction process.

FIG. 7 is an explanatory view schematically illustrating SOC-OCV characteristics of a storage battery 12.

FIG. 8 is a flowchart showing a correction process in a modification.

### DESCRIPTION OF EMBODIMENTS

### A. Embodiment

### A-1. Configuration of Battery Device 100:

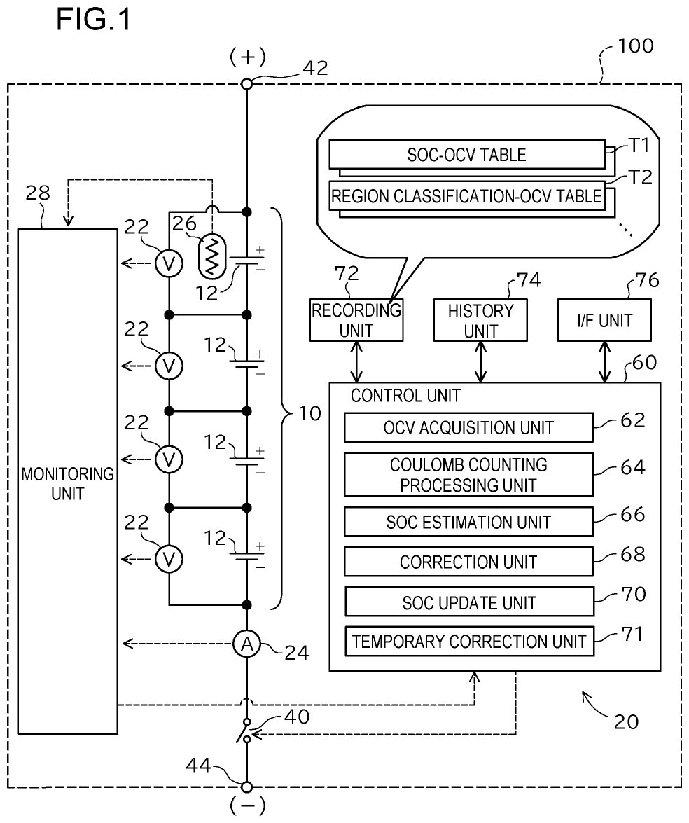

FIG. 1 is an explanatory view schematically illustrating a configuration of a battery device 100 in an embodiment. The battery device 100 includes a battery assembly 10 and a storage battery management device 20.

The battery assembly 10 has a configuration in which a plurality of the storage batteries 12 are connected in series. In this embodiment, the battery assembly 10 consists of four storage batteries 12. The battery assembly 10 is connected to a load and an external power source, not shown, via a positive terminal 42 and a negative terminal 44.

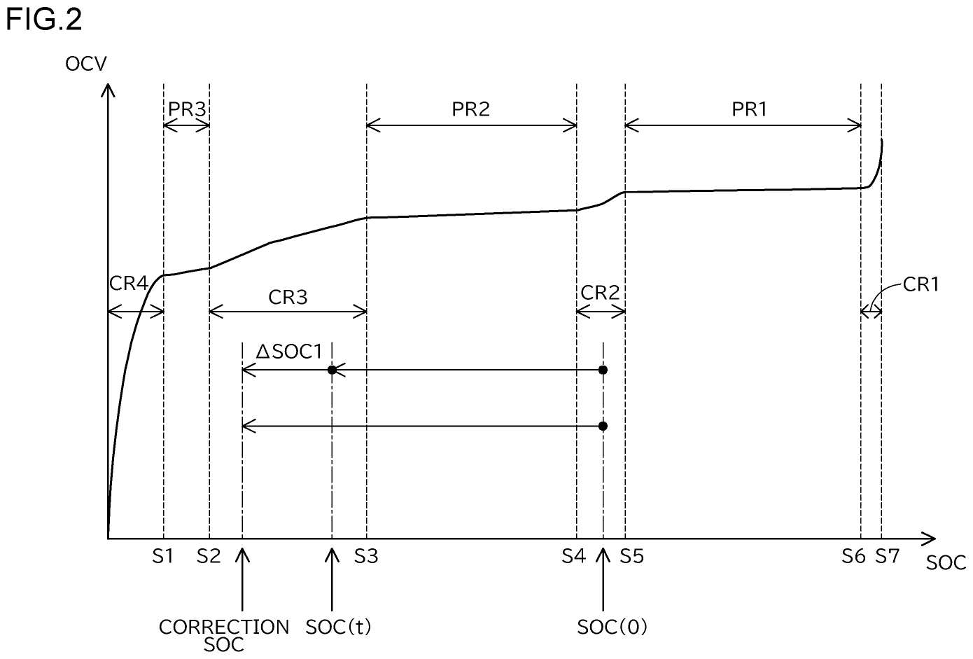

Each of the storage batteries 12 constituting the battery assembly 10 is a storage battery having SOC (state of charge)-OCV (open circuit voltage) characteristics that include a plateau region PR. FIG. 2 is an explanatory view schematically illustrating SOC-OCV characteristics of the storage battery 12. The plateau region PR is a region where the curve representing the SOC-OCV characteristics is almost flat, or more specifically, where the OCV change rate (absolute value of OCV change relative to SOC change) is 2 mV/% or less. Examples of the storage battery 12 having SOC-OCV characteristics with the plateau region PR may include iron phosphate lithium-ion batteries and titanic acid lithium-ion batteries. The SOC-OCV characteristics of the storage battery 12 further includes a change region CR. The change region CR is a region where the OCV change rate exceeds 2 mV/% (non-plateau region). As shown in FIG. 2, three plateau regions PR (first plateau region PR1, second plateau region PR2, and third plateau region PR3) and four change regions CR (first change region CR1, second change region CR2, third change region CR3, and fourth change region CR4) appear alternately in the SOC-OCV characteristics of the storage battery 12. The plateau region PR is an example of the first region in the claims, the change region CR is an example of the second region in the claims, and 2 mV/% is an example of the predetermined value in the claims.

The storage battery management device 20 is a device for managing the battery device 100 including the battery assembly 10. The storage battery management device 20 includes a voltmeter 22, an ammeter 24, a thermometer 26, a monitoring unit 28, a line switch 40, a control unit 60, a recording unit 72, a history unit 74, and an interface (I/F) unit 76.

One voltmeter 22 is provided for each storage battery 12. Each voltmeter 22 is connected in parallel to each storage battery 12, measures the voltage of each storage battery 12, and outputs a signal indicating the voltage measurement to the monitoring unit 28. The ammeter 24 is connected in series to the battery assembly 10. The ammeter 24 measures the current flowing through the battery assembly 10 and outputs a signal indicating the measured current to the monitoring unit 28. The thermometer 26 is located near the battery assembly 10. The thermometer 26 measures the temperature of the battery assembly 10 (each storage battery 12) and outputs a signal indicating the temperature measurement value to the monitoring unit 28. Based on the signals received from the voltmeter 22, the ammeter 24, and the thermometer 26, the monitoring unit 28 outputs signals indicating the voltage of each storage battery 12, the current flowing through the battery assembly 10, and the temperature of the battery assembly 10 (each storage battery 12) to the control unit 60. The combination of the voltmeter 22 and the monitoring unit 28 is an example of the voltage measurement unit, the combination of the ammeter 24 and the monitoring unit 28 is an example of the current measurement unit, and the combination of the thermometer 26 and the monitoring unit 28 is an example of the battery temperature measurement unit.

The line switch 40 is provided between the battery assembly 10 and the negative terminal 44. The line switch 40 is controlled on and off by the control unit 60 to open and close the connection between the battery assembly 10 and the load/external power source.

The control unit 60 is configured by using, e.g., a CPU, a multi-core CPU, or a programmable device (such as a field programmable gate array (FPGA), a programmable logic device (PLD)) to control the operation of the storage battery management device 20. The control unit 60 has functions as an OCV acquisition unit 62, a coulomb counting processing unit 64, an SOC estimation unit 66, a correction unit 68, an SOC update unit 70, and a temporary correction unit 71. The functions of each of these units will be described in conjunction with the description of the SOC estimation process below.

The recording unit 72 is composed of, e.g., ROM, RAM, a hard disk drive (HDD), and is used to store various programs and data, or as a work area or data storage area when executing various processes. For example, the recording unit 72 stores a computer program for executing the SOC estimation process described below. The computer program is provided, e.g., in the form of a computer-readable recording medium (not shown) such as a CD-ROM, DVD-ROM, and USB memory, and is stored in the recording unit 72 by being installed in the battery device 100.

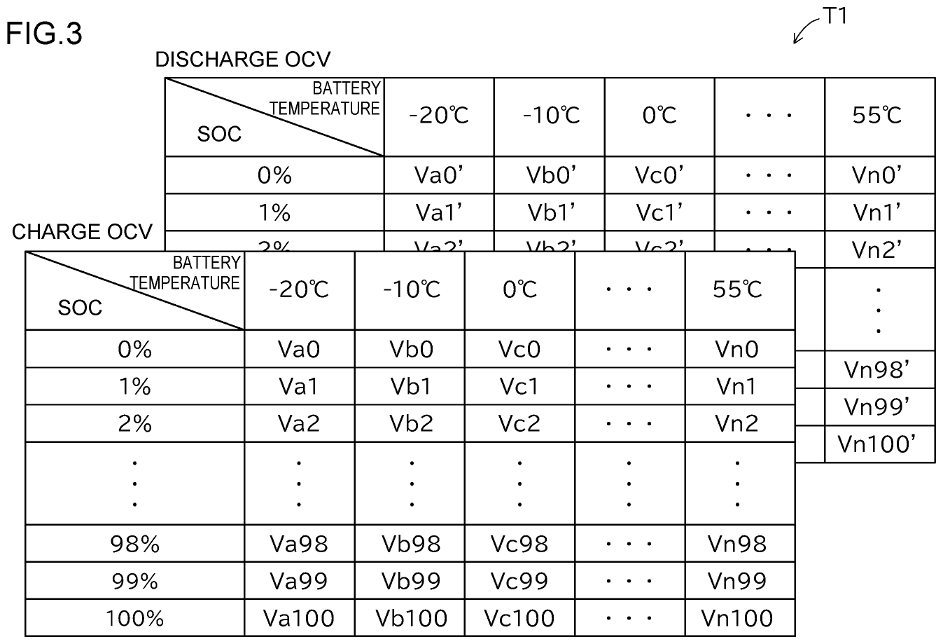

The recording unit 72 also stores an SOC-OCV table T1 and a region classification-OCV table T2. The SOC-OCV table T1 is a table used for SOC estimation based on the OCV method for each of the storage batteries 12. FIG. 3 is an explanatory view illustrating an example of the SOC-OCV table T1. The SOC-OCV table T1 is a table that associates the OCV, the battery temperature, and the SOC. The relationship specified in the SOC-OCV table T1 is experimentally determined in advance. As shown in FIG. 3, the SOC-OCV characteristics fluctuate with changes in battery temperature. By referring to the SOC-OCV table T1, the SOC of each storage battery 12 can be estimated based on the OCV of each storage battery 12 and the battery temperature. In FIG. 3, the OCV is indicated as Va0, Va1, . . . , but the actual SOC-OCV table T1 defines the numerical value of the OCV. In addition, FIG. 3 shows the SOC-OCV table for discharge, which is used when discharging the storage battery 12, and the SOC-OCV table for charge, which is used when charging the storage battery 12.

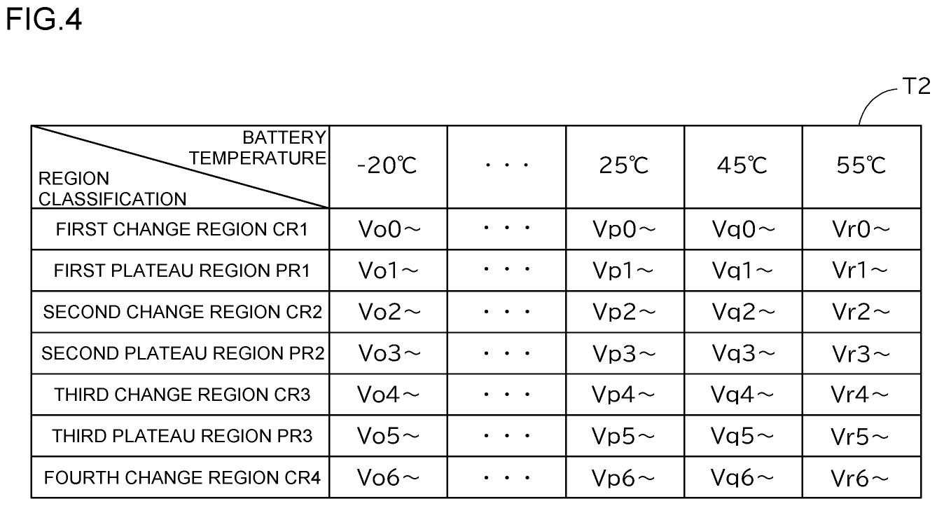

The region classification-OCV table T2 (FIG. 1) recorded in the recording unit 72 is used to determine in which region (plateau region PR, change region CR) the estimated SOC is located (belongs to which region) in the SOC-OCV characteristics. FIG. 4 is an explanatory view illustrating an example of region classification-OCV table T2. In this embodiment, the region classification-OCV table T2 defines the relationship among the OCV, each region classification in the SOC-OCV characteristics, and the battery temperature. As mentioned above, since the SOC-OCV characteristics fluctuate in accordance with changes in battery temperature, each region classification in the SOC-OCV characteristics fluctuates in accordance with the fluctuation of the SOC-OCV characteristics. In FIG. 4, the OCV is indicated as Vo0, Vo1, . . . , but the actual region classification-OCV table T2 defines the numerical value of the OCV.

The history unit 74 is composed of, e.g., ROM, RAM, and a hard disk drive (HDD), and records various histories related to the battery device 100. Such history includes, e.g., the OCV of the storage battery 12 and the correction details of the FCC correction process and the temporary correction process described below. The interface unit 76 communicates with other devices by wired or wireless means. For example, the history recorded in the history unit 74 is updated by communication with other devices via the interface unit 76.

### A-2. SOC Estimation Process:

Next, the SOC estimation process performed by the storage battery management device 20 in the battery device 100 of this embodiment is described. In this embodiment, the SOC estimation process is a process to mainly perform the SOC estimation based on the current integration method, and when the correction SOC acquired by the OCV method is in the change region CR, to correct the FCC (full charge capacity) used for the SOC estimation based on the current integration method, according to the correction SOC. In this embodiment, the SOC estimation process estimates the SOC individually for each of the storage batteries 12 that constitute the battery assembly 10. The following description focuses on one storage battery 12. The SOC estimation process is started, e.g., automatically when the storage battery management device 20 is activated or in response to instructions from the administrator.

### A-2-1. Estimation Process of Integrated SOC(t):

The battery device 100 of this embodiment performs a process to estimate the SOC based on the current integration method (hereinafter referred to as “integrated SOC(t)”). Specifically, the coulomb counting processing unit 64 (FIG. 1) of the storage battery management device 20 calculates the capacity of each storage battery 12 by integrating the currents measured by the ammeter 24 and the monitoring unit 28. Next, the SOC estimation unit 66 of the storage battery management device 20 estimates the integrated SOC(t) of the storage batteries based on the reference time SOC(0) (the SOC at the reference time), the change amount of the capacity Q(t) (charge transfer) of the storage batteries 12 from the reference time calculated by the coulomb counting processing unit 64, and the FCC of the storage batteries 12. The integrated SOC(t) can be represented by the following Equation (1).

integrated SOC(t)=reference time SOC(0)+[Q(t)/FCC] (1)

At the start of the SOC estimation process, the reference time is the time at which the battery device 100 is shipped, and thereafter, the reference time is the time at which the reference SOC update process is performed in the correction process described below. The estimation process of the integrated SOC(t) is continuously performed during the SOC estimation process.

### A-2-2. OCV Acquisition Process:

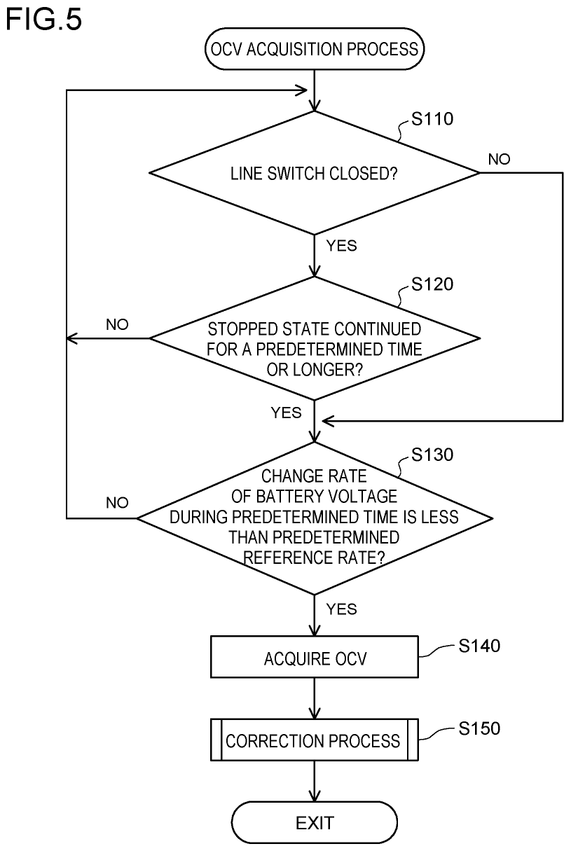

FIG. 5 is a flowchart showing an OCV acquisition process performed in the battery device 100. When the current of charge or discharge to/from the storage battery 12 falls below a predetermined threshold value or when the line switch 40 shifts from the closed state to the open state, the control unit 60 determines that the storage battery 12 is in an stopped state, and the OCV acquisition unit 62 (FIG. 1) of the storage battery management device 20 executes the OCV acquisition process (FIG. 5) for the storage battery 12. Specifically, the OCV acquisition unit 62 determines whether or not the OCV acquisition timing has arrived, and if it determines that the OCV acquisition timing has arrived, the OCV acquisition unit 62 performs the OCV acquisition process (S110 to S140). In this embodiment, the OCV acquisition timing for the storage battery 12 is the timing at which the polarization of the storage battery 12 has resolved to stabilize the battery voltage to the extent that the OCV of the storage battery 12 can be acquired.

As shown in FIG. 5, the OCV acquisition unit 62 (FIG. 1) of the control unit 60 again determines whether the line switch 40 is in the closed state (S110). The line switch 40 being in the closed state means that the storage battery 12 (battery assembly 10) is electrically connected to a load, and the line switch 40 being in the open state means that the storage battery 12 is in the no-load state, not electrically connected to a load (not shown).

When the OCV acquisition unit 62 determines that the line switch 40 is in the closed state (S110: YES), the OCV acquisition unit 62 determines whether the stopped state in which no current flows to the storage battery 12 has continued for a predetermined time or longer (S120). The control unit 60 always determines the presence or absence of current flowing through the storage battery 12 based on the signals input from the monitoring unit 28 and keeps the results of the determination as a history associated with the elapsed time, and the OCV acquisition unit 62 can determine whether the stopped state of the storage battery 12 has continued for a predetermined time or longer based on this history. The OCV acquisition unit 62 determines that the current state of the storage battery 12 is in a stopped state if the current flowing through the storage battery 12 is a reference current value (a value at which the current can be regarded as approximately zero) or less. The measurement of the current in storage battery 12 is continuously performed during the SOC estimation process.

If the OCV acquisition unit 62 determines that the stopped state of the storage battery 12 has not continued for a predetermined time or longer (S120: NO), the process returns to S110. In contrast, if the OCV acquisition unit 62 determines that the stopped state of the storage battery 12 has continued for a predetermined time or longer (S120: YES), the OCV acquisition unit 62 determines, based on the signal input from the monitoring unit 28, whether the change rate of the battery voltage of the storage battery 12 during the predetermined time is less than a predetermined reference rate (a value at which the battery voltage of the storage battery 12 is considered to be approximately stable) (S130). The measurement of the voltage of the storage battery 12 is continuously performed during the SOC estimation process.

If the OCV acquisition unit 62 determines that the change rate of the battery voltage of the storage battery 12 during the predetermined time is the reference rate or higher (S130: NO), the process returns to S110. In contrast, if the OCV acquisition unit 62 determines that the change rate of the battery voltage of the storage battery 12 during the predetermined time is less than the reference rate (S130: YES), the OCV acquisition unit 62 records the measured battery voltage of the storage battery 12 in the history unit 74 as the OCV of the storage battery 12 (S140), and the process proceeds to the correction process (S150).

### A-2-3. Correction Process:

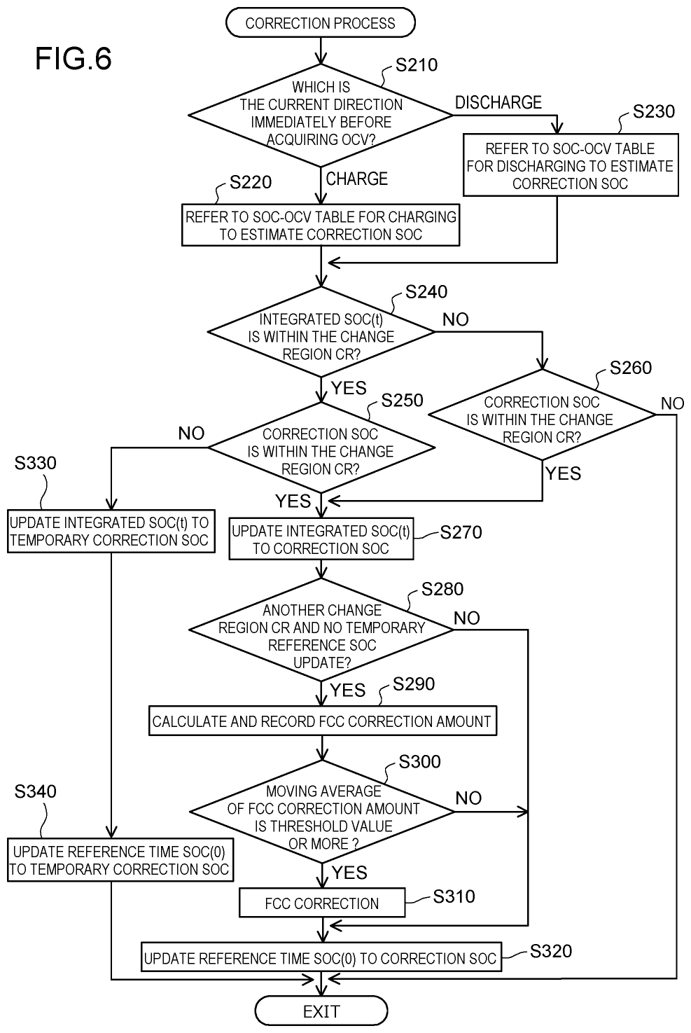

FIG. 6 is a flowchart showing the correction process. The correction process is a process to update the reference time SOC(0) used for the integrated SOC(t) estimation process and to correct the integrated SOC(t) and FCC of the storage battery 12.

### Estimation Process of Correction SOC:

In this embodiment, the SOC corresponding to the OCV of the storage battery 12 acquired in the OCV acquisition process (hereinafter referred to as “correction SOC”) is first estimated. Specifically, it is determined whether the current state of the storage battery 12 immediately before shifting to the stopped state is a charging state or a discharging state (S210). For example, the signal output from the ammeter 24 corresponds to the presence/absence and direction of the current flowing through the storage battery 12 (a signal corresponding to the high and low voltage at both ends of the detection resistor (not shown) provided in the ammeter 24), and the control unit 60 determines the current state (charge state, discharge state, or stopped state) of the storage battery 12 based on the level of the signal output from the ammeter 24 and the level reversal of that signal. If the control unit 60 determines that the current state of the storage battery 12 immediately before shifting to the stopped state is the charging state, the control unit 60 refers to the SOC-OCV table for charging recorded in the recording unit 72 to estimate the SOC corresponding to the OCV acquired in the OCV process as the correction SOC (S220). If the control unit 60 determines that the current state of the storage battery 12 immediately before shifting to the stopped state is the discharged state, the control unit 60 refers to the SOC-OCV table for discharge recorded in the above recording unit 72 to estimate the SOC corresponding to the OCV acquired in the OCV process as the correction SOC (S230).

(Region Determination Process to Determine Region to which Each SOC Belongs):

The control unit 60 of the storage battery management device 20 determines which region (plateau region PR or change region CR) in the SOC-OCV characteristics of the storage battery 12 the integrated SOC(t) and the correction SOC belong to, respectively, based on the integrated SOC(t) at the current time (at which the OCV is acquired), the correction SOC, and the region classification-OCV table T2. As explained below, in this embodiment, depending on the combination of the regions to which the integrated SOC(t) and the correction SOC belong, respectively, whether the correction processing is performed or not and, if performed, the content of the correction is determined.

### (Integrated SOC Update Process):

The integrated SOC update process is a process to update (reset) the integrated SOC(t) to the correction SOC. When it is determined that both the integrated SOC(t) and the correction SOC are within the change region CR (S240: YES and S250: YES), the SOC update unit 70 (FIG. 1) of the storage battery management device 20 performs the integrated SOC update process (S270). Also, when it is determined that the integrated SOC(t) is within the plateau region PR and the correction SOC is within the change region CR (S240: NO and S260: YES), the SOC update unit 70 performs the SOC(t) update process (S270). In other words, the SOC update unit 70 performs the integrated SOC update process when the correction SOC is within the change region CR (hereinafter referred to as the “first condition”). When the correction SOC is within the change region CR, the estimation accuracy of the estimation process of the correction SOC (S220, S230) is higher than when the correction SOC is within the plateau region PR. Therefore, the accuracy of SOC estimation can be improved by performing the integrated SOC update process using the correction SOC estimated when the first condition is satisfied.

### (FCC Correction Process):

The FCC correction process is a process to correct the FCC of the storage battery 12 used in the estimation process of the integrated SOC(t) based on the above correction SOC. In this embodiment, the FCC correction process is performed when the following correction conditions are satisfied. The correction conditions include as necessary conditions the following conditions in addition to the first condition.

Second condition: the change region CR to which the reference time SOC(0) belongs and the change region CR to which the correction SOC belongs are different from each other. The control unit 60 can determine whether the second condition is satisfied based on the judgment result of the above region determination process.

Third condition: the temporary reference SOC update process (S340) described below has not been performed since the previous execution of the FCC correction process (S310). When the temporary reference SOC update process is performed, the execution information of the temporary reference SOC update process (such as the temporary correction SOC) is recorded in the history unit 74 as history information in association with the execution time. The control unit 60 can determine whether the third condition is satisfied based on the history information stored in the history unit 74.

Fourth condition: the average (moving average) of the FCC correction amount (e.g., the difference ΔSOC1 in FIG. 2) for the most recent predetermined number of times (two or more times) recorded in the history unit 74 is a threshold value or more. The FCC correction amount is recorded in the history unit 74 when the predetermined conditions (the first to third conditions in this embodiment) are satisfied in each correction process. The control unit 60 can determine whether the fourth condition is satisfied based on the above history information stored in the history unit 74.

Specifically, if it is determined that both the second and third conditions are satisfied (S280: YES), the control unit 60 calculates the FCC correction amount and records it in the history unit 74 as history information in association with the execution time of the current OCV acquisition process (S290). The FCC correction amount is the difference between the FCC after correction based on the correction SOC and the FCC before correction. The FCC after correction can be calculated by the following Equation (2).

FCC after correction=Q(t)/(correction SOC−reference time SOC(0)) (2)

The control unit 60 then calculates the FCC correction amount as the difference between the FCC after correction and the FCC before correction (=FCC after correction-FCC before correction). If it is determined that at least one of the second and third conditions is not satisfied (S280: NO), the calculation and recording of the FCC correction amount (S290) and the FCC correction process (S310) are not performed, and the process proceeds to S320.

If it is determined that the fourth condition is satisfied (S300: YES), the correction unit 68 executes the FCC correction process described above (S310). Specifically, the correction unit 68 corrects the FCC of the storage battery 12 used in the estimation process of the integrated SOC(t) to the FCC after correction, and the process proceeds to S320. If it is determined that the fourth condition is not satisfied (S300: NO), the FCC correction process is not performed, and the process proceeds to S320.

### (Reference SOC Update Process):

In S320, the SOC update unit 70 executes the reference SOC update process. The reference SOC update process is a process to update (reset) the reference time SOC(0) in Equation (1), which is used in the estimation process of the integrated SOC(t), to the correction SOC. When the correction SOC is in the change region CR, the estimation process (S220, S230) of the correction SOC is more accurate than when the correction SOC is in the plateau region PR. Therefore, when the first condition is satisfied, performing the reference SOC update process can improve the accuracy of the estimation process of the integrated SOC(t) in subsequent processes. If it is determined that both the integrated SOC(t) and the correction SOC are within the plateau region PR (S240: NO and S260: NO), the FCC correction process and the reference SOC update process are not performed.

The control unit 60 may estimate the SOH (state of health) of the storage battery 12 based on the corrected FCC and communicate the FCC after correction to the outside world via the interface unit 76. The control unit 60 estimates the SOH of the storage battery 12 based on the FCC of the new storage battery 12 recorded in the recording unit 72 in advance and the FCC after correction.

### (Temporary Correction Process):

The temporary correction process is a process to update (reset) the integrated SOC(t) to a temporary correction SOC when the correction SOC is within the plateau region PR, as well as to update (reset) the reference time SOC(0) in the Equation (1) used in the estimation process of the integrated SOC(t) to the temporary correction SOC. In this embodiment, when it is determined that the integrated SOC(t) is within the change region CR and the correction SOC is within the plateau region PR (S240: YES and S250: NO), the temporary correction unit 71 (FIG. 1) of the storage battery management device 20 performs the temporary integrated SOC update process (S330). In the temporary integrated SOC update process, the temporary correction unit 71 determines, in the plateau regions PR where the correction SOC is located, the SOC closest to the integrated SOC(t) as the temporary correction SOC and updates the integrated SOC(t) to the temporary correction SOC. In this way, updating the integrated SOC using the temporary correction SOC can improve the accuracy of SOC estimation.

Next, the temporary correction unit 71 executes the temporary reference SOC update process (S340). In the temporary reference SOC update process, the temporary correction unit 71 updates the reference time SOC(0) to the temporary correction SOC. Performing the temporary reference SOC update process can improve the accuracy of the estimation process of the integrated SOC(t) in subsequent processes.

### A-3. Effects of Embodiment:

As described above, the storage battery management device 20 of this embodiment is a device for managing a battery assembly 10 in which a plurality of the storage batteries 12 having SOC-OCV characteristics including a plateau region PR are connected in series. The storage battery management device 20 includes the ammeter 24, the thermometer 26, the monitoring unit 28, the OCV acquisition unit 62, the coulomb counting processing unit 64, the SOC estimation unit 66, the correction unit 68, the SOC update unit 70, the temporary correction unit 71, and the control unit 60. The voltmeter 22 and the monitoring unit 28 measure the voltage of the storage battery 12. The ammeter 24 and the monitoring unit 28 measure the current flowing through the battery assembly 10. The coulomb counting processing unit 64 calculates the capacity of the storage battery 12 by integrating the current measured by the ammeter 24 and the monitoring unit 28 and the current during the constant current control described above.

The SOC estimation unit 66 estimates the SOC of the storage battery 12 based on the reference time SOC(0), the change amount of the capacity Q(t) of the storage battery 12 from the reference time calculated by the coulomb counting processing unit 64, and the FCC of the storage battery 12. The OCV acquisition unit 62 acquires the OCV of the storage battery 12. When the correction condition including as a necessary condition that the correction SOC, which is the SOC corresponding to the OCV of the storage battery 12 acquired by the OCV acquisition unit 62, is within the change region CR (the first condition, S250: YES or S260: YES in FIG. 6) is satisfied, the correction unit 68 corrects the estimated SOC estimated by the SOC estimation unit 66 and the FCC of the storage battery 12 used by the SOC estimation unit 66 based on the correction SOC (S310).

The correction SOC is the SOC corresponding to the OCV of the storage battery 12 acquired by the OCV acquisition unit 62 and the SOC that is within the change region CR. When the SOC is within the change region CR, the accuracy of acquiring the SOC corresponding to the OCV is higher than when the SOC is within the plateau region PR. The correction SOC acquired with this relatively high accuracy reflects the state error of the storage battery 12 (such as individual differences of the storage batteries 12 at the time of shipment or the manufacturing stage and aging) more accurately than the integrated SOC(t) estimated based on the current integration method by virtue of the fact that there is no integration error. Therefore, this correction SOC can be used to accurately correct the FCC used for the estimation process of the integrated SOC(t). As a result, this embodiment can perform the estimation process of the integrated SOC(t) more accurately than in the configuration where the FCC is not corrected.

In this embodiment, since the FCC is corrected based on the difference between the reference time SOC(0) and the correction SOC (S310), which is correlated with the state error of the storage battery 12, the estimation process of the integrated SOC(t) can be performed more accurately.

In this embodiment, the temporary correction process (S330, S340) is performed even when the correction SOC is not within the change region CR. As a result, according to this embodiment, the estimation process of the integrated SOC(t) can be performed more accurately than in the configuration without a temporary correction process.

In this embodiment, the FCC correction process is performed under the necessary condition (the fourth condition) that the average value of the FCC correction amount in the FCC correction process for the most recent predetermined number of times (two or more times) is a threshold value or more (S300: YES). This embodiment can suppress the reduction in the accuracy of the FCC correction due to, e.g., noise or measurement error of the ammeter 24.

In this embodiment, the FCC correction process is performed under the necessary condition (the second condition) that the change region CR to which the reference time SOC(0) belongs and the change region CR to which the correction SOC belongs are different from each other (S280: YES). This embodiment can reduce the burden of performing the FCC correction that would otherwise be performed even when, e.g., the reference time SOC(0) and the correction SOC are within the same change region CR, and the amount of charge transfer in the storage battery 12 is extremely small and does not require FCC correction.

In this embodiment, the FCC correction process is performed under the necessary condition (the third condition) that the temporary correction process described below has not been performed since the last time the FCC correction process was performed (S280: YES). This embodiment can suppress errors caused, e.g., by the execution of temporary correction, from having an adverse effect on the judgment of whether or not FCC correction is necessary.

For example, in the example shown in FIG. 2, since both the integrated SOC(t) and the correction SOC are within the third change region CR3 (S240: YES and S250: YES in FIG. 6), the integrated SOC update process (S270) and the reference SOC update process (S320) are performed, and the integrated SOC(t) and the reference time SOC(0) are updated to the correction SOC. There is a difference ΔSOC1 between the integrated SOC(t) and the correction SOC due to the effect of the state error of the storage battery 12 and other factors. In the present embodiment, since the reference time SOC(0) and the correction SOC are in different change regions CR2 and CR3 (S280: YES), the FCC correction process is performed. It should be noted that even when the reference time SOC(0) and the correction SOC are in the same change region (S280: NO), the FCC correction process may be performed if the difference between the reference time SOC(0) and the correction SOC is a lower limit or more.

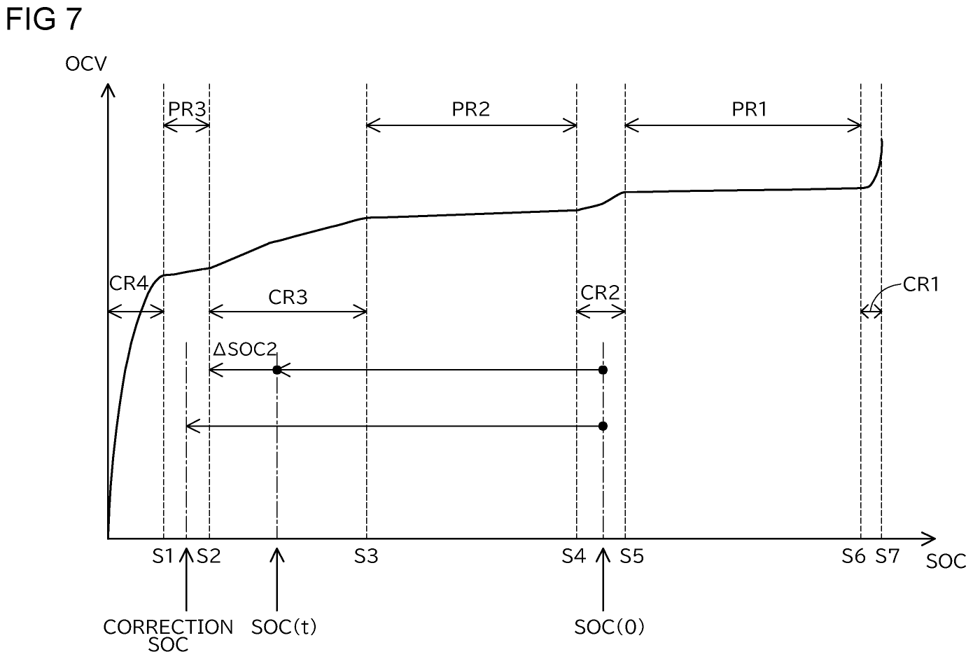

FIG. 7 is an explanatory view schematically illustrating SOC-OCV characteristics of a storage battery 12. In the example shown in FIG. 7, the integrated SOC(t) is within the third change region CR3, but the correction SOC is within the third plateau region PR3 (S240: YES and $250: NO in FIG. 6); therefore, the FCC correction process is not performed and instead, the temporary integrated SOC update process (S330) and the temporary reference SOC update process (S340) are performed. In the temporary integrated SOC update process and the temporary reference SOC update process, the SOC value S2 closest to the integrated SOC(t) in the third plateau region PR3 is determined as the temporary correction SOC, and based on this temporary correction SOC, the integrated SOC(t) and the reference time SOC(0) of the storage battery 12 used in the estimation process of the integrated SOC(t) are temporarily corrected. Therefore, the estimation process of the integrated SOC(t) can be performed more accurately than when the temporary reference SOC update process is not performed. However, since the difference ΔSOC2 between the integrated SOC(t) and the value S2 of the SOC may not accurately reflect the state error of the storage battery 12, the FCC correction may be less accurate than the FCC correction process. Therefore, as described above, if the third condition is not satisfied (S280: NO), the FCC correction amount calculation and recording (S290) and the FCC correction process (S310) are not performed.

### B. Modifications

The technology disclosed herein is not limited to the embodiments described above but can be modified into various forms without departing from the spirit of the present invention; for example, the following modifications are possible.

The configuration of the battery device 100 in the above embodiments is only an example and can be modified in various ways. For example, in each of the above embodiments, the number of the storage batteries 12 constituting the battery assembly 10 can be modified as desired. In the above embodiments, one thermometer 26 may be provided for each of the storage batteries 12. The thermometer 26 may be omitted.

In the above embodiment, an iron phosphate lithium-ion battery is exemplified as the storage battery, but any other secondary or primary battery may be used as long as the storage battery has SOC-OCV characteristics that include a first region where the OCV change rate is a predetermined value or less, and a second region where the OCV change rate exceeds the predetermined value. The predetermined value is not limited to 2 mV/% but can be freely selected. The number of first and second regions can be freely changed.

In the above embodiment, the contents of the SOC-OCV table T1 and the region classification-OCV table T2 are only examples and can be modified in various ways. The SOC-OCV table T1 and/or the region classification-OCV table T2 need not be recorded in the recording unit 72. Also, in each of the above embodiments, at least one of each functional part of the control unit 60 may be omitted.

The content of the SOC estimation process in the above embodiments is only an example and can be modified in various ways. For example, in the above embodiment, the SOC estimation process is to estimate SOC individually for each of the storage batteries 12 constituting the battery assembly 10, but the SOC may be estimated for the entire battery assembly 10. In the OCV acquisition process in the above embodiment, the method of acquiring the battery voltage of the storage batteries 12 in a stable state as the OCV was adopted (S110 to S130 in FIG. 5), but a known method may be adopted, such as a method of estimating the OCV based on changes in the internal resistance and the battery voltage of the storage batteries 12.

In the SOC estimation process in the above embodiment, the reference SOC update process (S320) may not be performed. Even in such a configuration, performing the FCC correction process can improve the accuracy of the estimation process of the integrated SOC(t). The correction conditions for executing the FCC correction process may not include at least one of the second to fourth conditions. The correction condition may further include as a necessary condition, e.g., that the temporary correction is not performed for a period corresponding to the above-predetermined number of times. This can suppress errors due to the execution of a temporary correction from adversely affecting the determination of whether or not the FCC correction is necessary. The correction condition may further include as a necessary condition that the difference between the reference time SOC(0) and the correction SOC is a lower limit or more. This can reduce the burden of performing the FCC correction that would otherwise be performed even when, e.g., the difference between the reference time SOC(0) and the correction SOC (the amount of charge transferred in the storage battery 12) is very small and does not require FCC correction. The correction condition may further include as a necessary condition that the temperature measured by the thermometer 26 is within a predetermined temperature range. This can suppress a decrease in the accuracy of the FCC correction due to the temperature of the storage battery 12 being outside the predetermined temperature range.

In the FCC correction process (S310) of the above embodiment, as an example of correcting the FCC according to the difference between the reference time SOC(0) and the correction SOC, the FCC is corrected by replacing the integrated SOC(t) by the current integration method with the correction SOC by the OCV method to substitute it into the FCC calculation equation (2); however, for example, the FCC may be corrected by replacing the integrated SOC(t) by the current integration method (e.g., 30%) with an SOC(e.g., 27%) that is closer to the correction SOC(e.g., 20%) than the integrated SOC(t) to substitute it into the FCC calculation formula to correct the FCC. In the FCC process, the FCC may be corrected according to the difference between the integrated SOC(t) by the current integration method and the correction SOC.

In the temporary correction process (S320) of the above embodiment, in the plateau region PR where the correction SOC is located, the SOC closest to the integrated SOC(t) (the SOC at the boundary between the plateau region PR and the change region CR) is determined as the temporary correction SOC; however, an SOC slightly outside of the integrated SOC(t) may be determined as the temporary correction SOC if the SOC is on the side of the integrated SOC(t).

In the above embodiment, the history of the FCC correction amount is recorded in the history unit 74 (S290); however, any history of the correction (e.g., a history of information correlated to the FCC correction amount) may be recorded, e.g., a history of the FCC value may be recorded in the history unit 74.

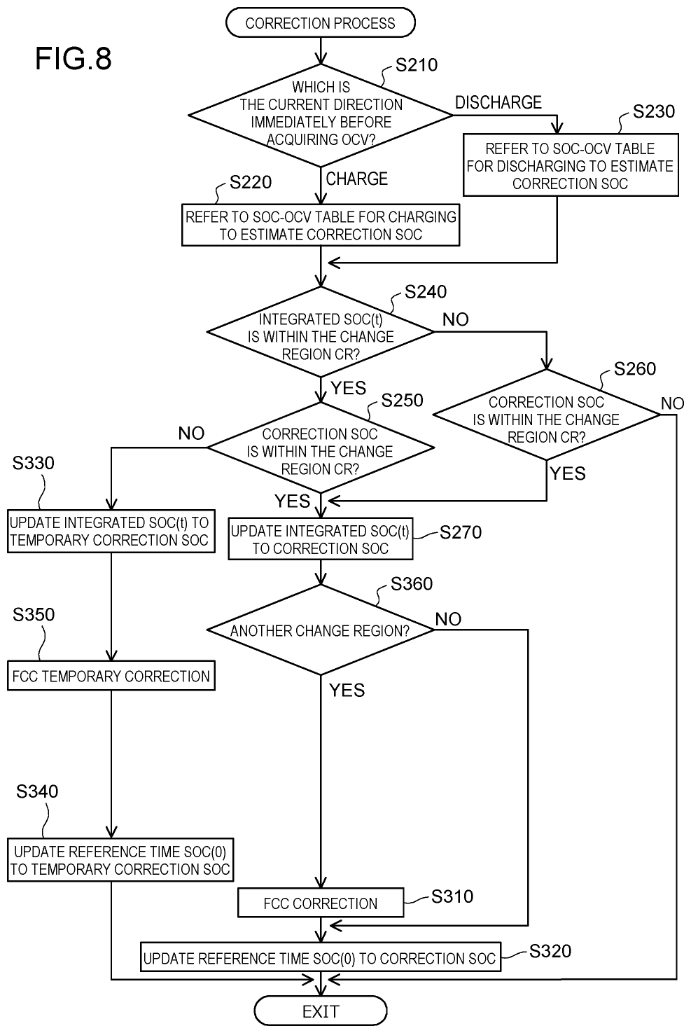

FIG. 8 is a flowchart showing the correction process in a modification. As shown in FIG. 8, in this modification, when it is determined that the second condition is satisfied (S360: YES), the calculation and recording of the FCC correction amount (S290) and the determination process for the fourth condition (S300) shown in FIG. 6 are not performed, and the FCC correction process (S310) is performed. After the execution of the temporary integrated SOC update process (S330), the temporary correction unit 71 performs the FCC temporary correction process (S350). The FCC temporary correction process is a process to temporarily correct the FCC of the storage battery 12 used in the estimation process of the integrated SOC(t). In the FCC temporary correction process, the FCC of the storage battery 12 used in the estimation process of the integrated SOC(t) is corrected to the FCC after temporary correction. After the FCC temporary correction process is completed, the temporary reference SOC update process is performed (S340). This allows the FCC temporary correction process to accurately perform the SOC estimation based on the current integration method even when the correction SOC is not in the change region CR.

### REFERENCE SIGNS LIST

10: battery assembly, 12: storage battery, 20: storage battery management device, 22: voltmeter, 24: ammeter, 26: thermometer, 28: monitoring unit, 40: line switch, 42: positive terminal, 44: negative terminal, 60: control unit, 62: OCV acquisition unit, 64: coulomb counting processing unit, 66: SOC estimation unit, 68: correction unit, 70: SOC update unit, 71: temporary correction unit, 72: recording unit, 74: history unit, 76: interface unit, 100: battery device, CR: change region, PR: plateau region

1. A storage battery management device for managing a storage battery having SOC-OCV characteristics including a first region in which an OCV change rate, which is the absolute value of a change amount of the OCV relative to the change amount of the SOC, is a predetermined value or less, and a second region in which the OCV change rate exceeds the predetermined value, comprising:
a current measurement unit that measures the current flowing through the storage battery;
a coulomb counting processing unit that calculates the capacity of the storage battery by integrating the current measured by the current measurement unit;
an SOC estimation unit that estimates the SOC of the storage battery based on a reference time SOC, the change amount of the capacity of the storage battery from the reference time calculated by the coulomb counting processing unit, and the FCC of the storage battery;
an OCV acquisition unit that acquires the OCV of the storage battery; and
a correction unit that corrects the FCC of the storage battery used in the SOC estimation unit based on the correction SOC when a correction condition is satisfied that includes as a necessary condition that the correction SOC, which is the SOC corresponding to the OCV of the storage battery acquired by the OCV acquisition unit, is within the second region.

2. The storage battery management device according to claim 1, wherein
the correction unit corrects the FCC of the storage battery used in the SOC estimation unit according to the difference between the reference time SOC and the correction SOC and the change amount of the capacity of the storage battery from the reference time.

3. The storage battery management device according to claim 1, further comprising:
a temporary correction unit that temporarily corrects the FCC of the storage battery based on a temporary correction SOC, which is a SOC on the estimated SOC side in the first region where the correction SOC is located when the correction SOC is in the first region, and the estimated SOC estimated by the SOC estimation unit is outside the first region where the correction SOC is located.

4. The storage battery management device according to claim 1, further comprising:
a history unit that records a history of the correction of the FCC of the storage battery in the correction unit each time the correction conditions are satisfied, wherein
the correction condition further includes as a necessary condition that an average value of the FCC correction amount for the most recent predetermined number of times (two or more times) recorded in the history unit is a threshold value or more.

5. The storage battery management device according to claim 4, further comprising:
a temporary correction unit that temporarily corrects the reference time SOC based on a temporary correction SOC, which is the SOC on the estimated SOC side in the first region where the correction SOC is located when the correction SOC is in the first region, and the estimated SOC estimated by the SOC estimation unit is outside the first region where the correction SOC is located, wherein
the correction condition further includes as a necessary condition that the temporary correction is not performed for a period corresponding to the predetermined number of times.

6. The storage battery management device according to claim 1, wherein
the SOC-OCV characteristics of the storage battery include a plurality of the second regions, and
the correction condition further includes as a necessary condition that the reference time SOC is within a second region different from the correction SOC.

7. The storage battery management device according to claim 1, wherein
the correction condition further includes as a necessary condition that the difference between the reference time SOC and the correction SOC is a lower limit or more.

8. The storage battery management device according to claim 1, further comprising:
a temperature measuring unit that measures the temperature of the storage battery, wherein
the correction condition further includes as a necessary condition that the temperature measured by the temperature measurement unit is within a predetermined temperature range.

9. The storage battery management device according to claim 1, further comprising:
an SOC update unit that updates the reference time SOC to the correction SOC when the correction condition is satisfied.

10. A method for managing a storage battery having SOC-OCV characteristics including a first region in which an OCV change rate, which is the absolute value of a change amount of the OCV relative to the change amount of the SOC, is a predetermined value or less, and a second region in which the OCV change rate exceeds the predetermined value, comprising:
a step of measuring a current flowing through the storage battery;
a step of calculating the capacity of the storage battery by integrating the measured current;
a step of estimating the SOC of the storage battery based on the reference time SOC, the calculated change amount of the capacity of the storage battery from the reference time, and the FCC of the storage battery;
a step of acquiring the OCV of the storage battery; and
a step of correcting the FCC of the storage battery used in the process of estimating the SOC of the storage battery based on the correction SOC when a correction condition is satisfied that includes as a necessary condition that the correction SOC, which is the SOC corresponding to the acquired OCV of the storage battery, is within the second region.

11. The storage battery management device according to claim 2, further comprising:
a temporary correction unit that temporarily corrects the FCC of the storage battery based on a temporary correction SOC, which is a SOC on the estimated SOC side in the first region where the correction SOC is located when the correction SOC is in the first region, and the estimated SOC estimated by the SOC estimation unit is outside the first region where the correction SOC is located.

12. The storage battery management device according to 2, further comprising:
a history unit that records a history of the correction of the FCC of the storage battery in the correction unit each time the correction conditions are satisfied, wherein
the correction condition further includes as a necessary condition that an average value of the FCC correction amount for the most recent predetermined number of times (two or more times) recorded in the history unit is a threshold value or more.

13. The storage battery management device according to claim 12, further comprising:
a temporary correction unit that temporarily corrects the reference time SOC based on a temporary correction SOC, which is the SOC on the estimated SOC side in the first region where the correction SOC is located when the correction SOC is in the first region, and the estimated SOC estimated by the SOC estimation unit is outside the first region where the correction SOC is located, wherein
the correction condition further includes as a necessary condition that the temporary correction is not performed for a period corresponding to the predetermined number of times.

14. The storage battery management device according to claim 2, wherein the SOC-OCV characteristics of the storage battery include a plurality of the second regions, and
the correction condition further includes as a necessary condition that the reference time SOC is within a second region different from the correction SOC.

15. The storage battery management device according to claim 2, wherein the correction condition further includes as a necessary condition that the difference between the reference time SOC and the correction SOC is a lower limit or more.

16. The storage battery management device according to claim 2, further comprising:
a temperature measuring unit that measures the temperature of the storage battery, wherein
the correction condition further includes as a necessary condition that the temperature measured by the temperature measurement unit is within a predetermined temperature range.

17. The storage battery management device according to claim 2, further comprising:
an SOC update unit that updates the reference time SOC to the correction SOC when the correction condition is satisfied.
